(19) United States
(12) Patent Application Publication
(10) Pub. No.: US 2023/0120662 A1
(43) Pub. Date: Apr. 20, 2023

(54) COOLING PLATE FOR SEMICONDUCTOR PROCESSING CHAMBER WINDOW

(71) Applicant: Lam Research Corporation, Fremont, CA (US)

(72) Inventor: Hanry Issavi, San Jose, CA (US)

(21) Appl. No.: 17/904,005

(22) PCT Filed: Feb. 8, 2021
(86) PCT No.: PCT/US2021/017125

§ 371 Date: Aug. 10, 2022

Related U.S. Application Data
(60) Provisional application No. 62/975,117, filed on Feb. 11, 2020.

(51) Int. Cl. H01J 37/32

(52) U.S. Cl. CPC H01J 37/32522; H01J 37/32119; H01J 2237/002; H01J 37/32816

(57) ABSTRACT

Cooling plates for radio-frequency transmissive windows in semiconductor processing chambers are disclosed. The cooling plates feature one or more sets of walls that, for each set, define a plurality of serpentine channels that are arranged in a circular array, thereby providing an annular region having serpentine channels extending therethrough. The cooling plate may be placed adjacent to the window and fluid may be flowed through it to provide cooling to the window. The cooling plates disclosed may require a much lower amount of total volumetric flow in order to achieve comparable or superior performance compared with traditional window cooling systems using air multipliers or air amplifiers.

### RELATED APPLICATION SECTION

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

In certain types of semiconductor processing chambers that utilize external radio frequency (RF) generators, RF-transmissive windows may be used to form part of the chamber such that RF energy from the RF generators may pass therethrough to cause a plasma within the chamber where a wafer is being processed. Such arrangements may, for example, be used in transformer-coupled plasma (TCP) reactors, in which a coil or other RF-emanating device is positioned above an RF-transmissive window that serves as the top of a semiconductor processing chamber.

Due to the processing conditions within such chambers, such windows may be subjected to high heat loads that may cause the windows to reach unsafe or undesirable temperatures. To counter such thermal effects, cooling systems are typically used that utilize multiple “air amplifiers” or “air multipliers” that direct clean dry air (CDA) provided, for example, by a facility CDA manifold or system, through nozzles at high velocity so that the jetting CDA draws additional ambient air from the facility itself into a common open plenum space above the window so as to cool the window. In an example such conventional cooling system, ^{˜}400-500 standard liters per minute (SLM) of CDA may be flowed through an air amplifier system to draw in an additional 2000 to 2500 SLM of facility ambient air that is used to cool such a window; as a result, between 2400 SLM and 3000 SLM (between 43 and 50 liters per second) of air flow may be flowed across the window being cooled by such a system. The velocity of air flow required to support such flow rates is quite high, and results in such systems generating a large amount of noise, e.g. on the order of 85 dB (comparable to the noise emitted by a milling machine or a food blender), as well as causing potentially undesirable air movement within a semiconductor processing facility due to the large volumes of air being displaced.

### SUMMARY

Details of one or more implementations of the subject matter described in this specification are set forth in the accompanying drawings and the description below. Other features, aspects, and advantages will become apparent from the description, the drawings, and the claims.

The present inventor conceived of a new and improved cooling system for RF-transmissive windows used in semiconductor processing chambers. The cooling systems discussed hereinbelow may allow the use of air amplifiers to be avoided and may be operated using only CDA from a CDA source, with no use of facility ambient air. These cooling systems are significantly quieter than traditional cooling systems used in such semiconductor processing chambers, generating, in some cases, less than 70 dB, i.e., more than 80% quieter than such traditional cooling systems. In addition to the above benefits that are provided by the cooling systems disclosed herein, such cooling systems may also allow for more uniform cooling of the windows with which they are used, e.g., a window cooled using a representative traditional cooling system may see temperature variations across the entire window of up to 40° C., whereas the same window may see temperature variations across the entire window of less than 15° C. if cooled using an improved cooling system such as one of the cooling systems discussed below. The cooling systems provided 2.0 below may also, generally speaking, be significantly cheaper, involve fewer parts and have a much smaller packaging volume than traditional cooling systems using air amplifiers.

The improved cooling systems discussed below may be generally described as involving a cooling plate having a ceiling portion, e.g., a generally planar surface that is parallel to the plane of the window and offset from the window by some distance to form a gap between the ceiling portion and the window, and one or more sets of walls extending from the ceiling portion towards the window so as to form a plurality of serpentine channels (or passages) that are arranged in one or more circular arrays around a common center axis. The walls may generally span the gap between the window and the ceiling portion, such that the window, in effect, forms a floor for the serpentine channels. In some instances, these structures may be integrated into the window itself, allowing the cooling solution to be an integral part of the window, which may provide for even quieter operation, smaller packaging requirements, and more effective cooling.

Such cooling systems may thus feature one or more annular areas that each have therewithin a circular array of serpentine channels through which CDA (or other fluid, e.g., gas or, in some cases, liquid) may be flowed in order to provide cooling to the window; multiple such annular areas may be provided, each with its own circular array of serpentine channels, for a given cooling system to allow for a “zoned” cooling solution in which different annular regions of the window may be subjected to different degrees of cooling e.g., through varying the volumetric flow rate of the fluid that is flowed through the serpentine channels of each annular region.

In some implementations, an apparatus may be provided that includes a cooling plate having a ceiling portion, one or more sets of walls, and a plurality of fluidic inlets. The walls in each set of walls may define, at least in part, a plurality of serpentine channels. Each serpentine channel may have a first end and a second end, the serpentine channels defined by each set of walls may be arranged in one or more circular patterns centered on a first axis of the cooling plate, the walls in each set of walls may protrude from the ceiling portion in a direction having a major component parallel to the first axis, and each fluidic inlet is fluidically connected with the first end of at least one of the serpentine channels within the cooling plate.

In some implementations, the apparatus may further include a semiconductor processing chamber having a radio-frequency transmissive window, and the cooling plate may be positioned against the window such that the window further defines the serpentine channels.

In some implementations, the apparatus may further include a pressurized air source, and the pressurized air source may be fluidically connected with at least one of the one or more fluidic inlets.

In some implementations, the one or more sets of walls may include a first set of walls and a second set of walls. The first set of walls may occupy a first annular region that has an outer diameter that is smaller than an inner diameter of a second annular region occupied by the second set of walls.

In some implementations, the serpentine channels defined by at least one set of walls of the one or more sets of walls may be open channels.

In some such implementations, the cooling plate may further include one or more floor portions. Each floor portion may be positioned so as to overlap one of the fluidic inlets when viewed along the first axis and offset from the ceiling portion so as to form a gap between the ceiling portion and that floor portion.

In some implementations, the cooling plate may further include a floor portion. In such implementations, the walls may include a first subset of walls that are closest to the first axis and a second subset of walls that are furthest from the first axis, the floor portion may span between the first subset of walls and the second subset of walls, and the walls of each set of walls may span between the ceiling portion and the floor portion.

In some such implementations, the ceiling portion, the floor portion, and the walls of the one or more sets of walls may be made of a material that is transmissive to radio frequency energy.

In some implementations, the one or more sets of walls may include a first set of walls and the first set of walls may define multiple pairs of serpentine channels, with each pair of serpentine channels including a first serpentine channel and a second serpentine channel. In such implementations, the first serpentine channel for each pair of serpentine channels may include a plurality of first and second flow-reversal sections such that fluid flowing from the first end to the second end of that first serpentine channel encounters the first and second flow-reversal sections thereof in an alternating fashion, the second serpentine channel for each pair of serpentine channels may include a plurality of third and fourth flow-reversal sections such that fluid flowing from the first end to the second end of that second serpentine channel encounters the third and fourth flow-reversal sections thereof in an alternating fashion, and the first flow-reversal sections of the first serpentine channel for each pair of serpentine channels and the third flow-reversal sections of the second serpentine channel for that pair of serpentine channels may be fluidically adjacent.

In some implementations, the one or more sets of walls may include a first set of walls and the first set of walls may include multiple subsets of walls, each subset of walls including a first radial wall, a second radial wall, one or more island walls, and one or more pairs of peninsular walls. In such implementations, each first radial wall may extend along a generally radial direction with respect to the first axis, each second radial wall may extend along a generally radial direction with respect to the first axis each pair of peninsular walls of each subset of walls may include a first peninsular wall that extends outward from the first radial wall of that subset of walls and a second peninsular wall that extends outward from the second radial wall of that subset of walls, the first peninsular wall and the second peninsular wall of each pair of peninsular walls of each subset of walls may extend outward and towards each other from the first radial wall of that subset of walls and the second radial wall of that subset of walls, respectively, a gap may exist between the first peninsular wall and the second peninsular wall of each pair of peninsular walls, each island wall of each subset of walls may be located between the first radial wall of that subset of walls and the second radial wall of that subset of walls, a first gap may exist between each island wall of each subset of walls and the first radial wall of that subset of walls, a second gap may exist between each island wall of each subset of walls and the second radial wall of that subset of walls, and the one or more island walls of each subset of walls and one or more pairs of peninsular walls of that subset of walls may be arranged in an alternating fashion along a corresponding second axis that intersects with, and is perpendicular to, the first axis such that one of the one or more island walls of that subset of walls is between every two adjacent pairs of peninsular walls of that subset of walls and one of the one or more pairs of peninsular walls of that subset of walls is between every two adjacent island walls of that subset of walls. In some implementations, the radial walls and the peninsular walls of the first set of walls may all be arcuate and concentric with one another.

In some implementations, the one or more sets of walls may include a first set of walls that includes multiple subsets of walls, each subset of walls including a first radial wall, a second radial wall, one or more first peninsular walls, and one or more second peninsular walls. In such implementations, for each subset of walls, each first radial wall may extend along a generally radial direction with respect to the first axis, each second radial wall may extend along a generally radial direction with respect to the first axis, each first peninsular wall for that subset of walls may extend outward from the first radial wall for that subset of walls towards the second radial wall for that subset of walls, each second peninsular wall for that subset of walls may extend outward from the second radial wall of that subset of walls towards the first radial wall for that subset of walls, each first peninsular wall for that subset of walls and each second peninsular wall for that subset of walls may be separated from the second radial wall for that subset of walls and the first radial wall for that subset of walls, respectively, by a corresponding gap, and the one or more first peninsular walls for that subset of walls and the one or more second peninsular walk for that subset of walls may be arranged in an alternating fashion along a corresponding second axis that intersects with, and is perpendicular to, the first axis such that every two adjacent pairs of peninsular walls for that subset of walls has a portion of one of the one or more island walls for that subset of walls therebetween and every two adjacent island walls for that subset of walls has a portion of one of the one or more pairs of peninsular walls therebetween.

In some implementations of the apparatus, the one or more sets of walls may include a first set of walls that includes multiple subsets of walls, each subset of walls including an inner wall, an outer wall, one or more first radial walls, and one or more second radial walls. In such implementations, for each subset of walls, each first radial wall for that subset of walls may extend radially inward from the outer wall for that subset of walls and with respect to the first axis, each second radial wall for that subset of walls may extend radially outward from the inner wall for that subset of walls and with respect to the first axis the inner wall for that subset of walls may be closer to the first axis than the outer wall for that subset of walls, and the one or more first radial walls for that subset of walls and the one or more second radial walls for that subset of walls may be arranged in an alternating fashion along an arcuate path centered on the first axis.

In some implementations of the apparatus, each set of walls may be (a) a first set of walls, (b) a second set of walls, or (c) a third set of walls. Each first set of walls of (a) may include multiple first subsets of walls, each first subset of walls including a first radial wall, a second radial wall, one or more island walls, and one or more pairs of peninsular walls. For each first subset of walls, each first radial wall may extend along a generally radial direction with respect to the first axis, each second radial wall may extend along a generally radial direction with respect to the first axis, each pair of peninsular walls for that first subset of walls may include a first peninsular wall that extends outward from the first radial wall of that first subset of walls and a second peninsular wall that extends outward from the second radial wall of that first subset of walls, the first peninsular wall and the second peninsular wall of each pair of peninsular walls of that first subset of walls may extend outward and towards each other from the first radial wall of that first subset of walls and the second radial wall of that first subset of walls, respectively, a gap may exist between the first peninsular wall and the second peninsular wall of each pair of peninsular walls for that first subset of walk, each island wall of that first subset of walls may be located between the first radial wall of that first subset of walls and the second radial wall of that first subset of walls, a first gap may exist between each island wall of that first subset of walk and the first radial wall of that first subset of walls, a second gap may exist between each island wall of that first subset of walls and the second radial wall of that first subset of walls, and the one or more island walls of that first subset of walls and one or more pairs of peninsular walls of that first subset of walls may be arranged in an alternating fashion along a corresponding second axis that intersects with, and is perpendicular to, the first axis such that one of the one or more island walls of that first subset of walls is between every two adjacent pairs of peninsular walls of that first subset of walls and one of the one or more pairs of peninsular walls of that first subset of walls is between every two adjacent island walls of that first subset of walls. Each second set of walls of (b) may include multiple second subsets of walls, each second subset of walls including a third radial wall, a fourth radial wall, one or more third peninsular walls, and one or more fourth peninsular walls. For each second subset of walls, each third radial wall may extend along a generally radial direction with respect to the first axis each fourth radial wall may extend along a generally radial direction with respect to the first axis, each third peninsular wall for that second subset of walls may extend outward from the third radial wall for that second subset of walls towards the fourth radial wall for that second subset of walls, each fourth peninsular wall for that second subset of walls may extend outward from the fourth radial wall of that second subset of walls towards the third radial wall for that second subset of walls, each third peninsular wall for that second subset of walls and each fourth peninsular wall for that second subset of walls may be separated from the fourth radial wall for that second subset of walls and the third radial wall for that second subset of walls, respectively, by a corresponding gap, and the one or more third peninsular walls for that second subset of walls and the one or more fourth peninsular walls for that second subset of walls may be arranged in an alternating fashion along a corresponding second axis that intersects with, and is perpendicular to, the first axis such that every two adjacent pairs of peninsular walls for that second subset of walls has a portion of one of the one or more island walls for that second subset of walls therebetween and every two adjacent island walls for that second subset of walls has a portion of one of the one or more pairs of peninsular walls therebetween. Each third set of walk of (c) may include multiple third subsets of walk, each third subset of walls including an inner wall, an outer wall, one or more fifth radial walls, and one or more sixth radial walls. For each third subset of walk, each fifth radial wall for that third subset of walls may extend radially inward from the outer wall for that third subset of walls and with respect to the first axis, each sixth radial wall for that third subset of walls may extend radially outward from the inner wall for that third subset of walls and with respect to the first axis, the inner wall for that third subset of walls may be closer to the first axis than the outer wall for that third subset of walls, and the one or more fifth radial walls for that third subset of walls and the one or more sixth radial walls for that third subset of walls may be arranged in an alternating fashion along an arcuate path centered on the first axis.

### BRIEF DESCRIPTION OF THE DRAWINGS

FIG. 1 depicts an example of a transformer-coupled plasma (TCP) reactor.

FIG. 2 depicts an isometric view of the underside of an example cooling plate.

FIG. 3 depicts a perspective view of the underside of the example cooling plate of FIG. 2 showing further details thereof.

FIG. 4A depicts a plan view of the underside of the example cooling plate of FIG. 2 emphasizing a first set of walls.

FIG. 46 depicts the plan view of FIG. 4A but emphasizing a second set of walls.

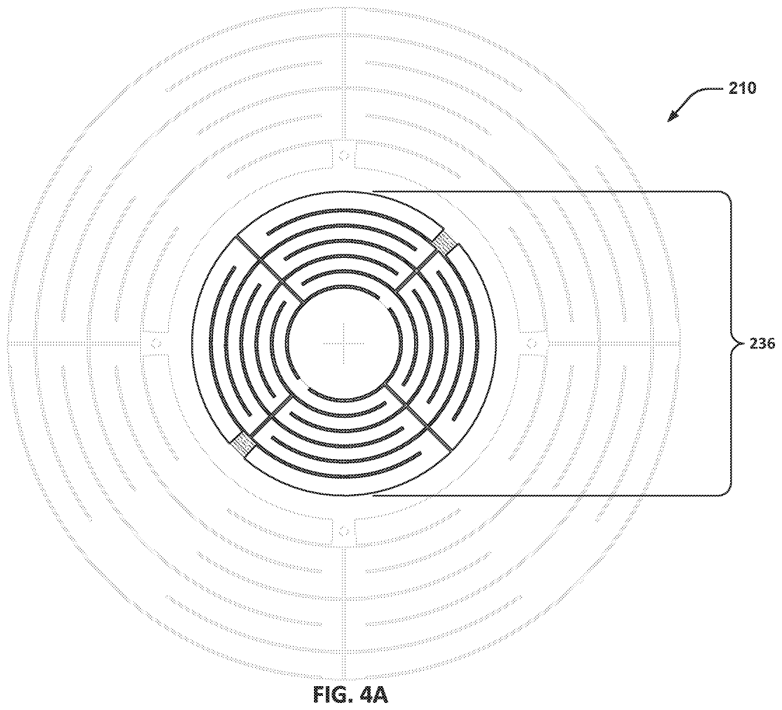

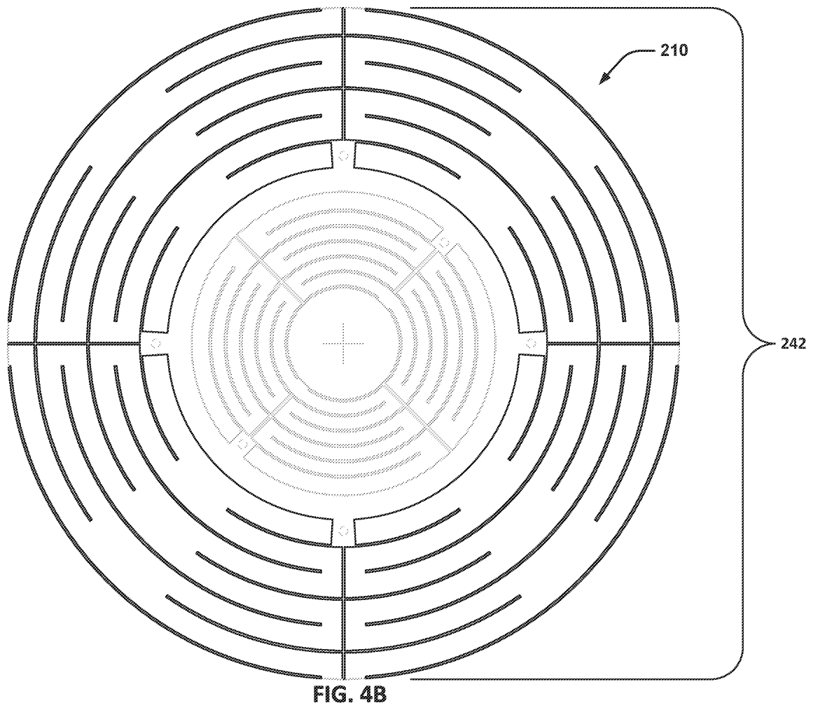

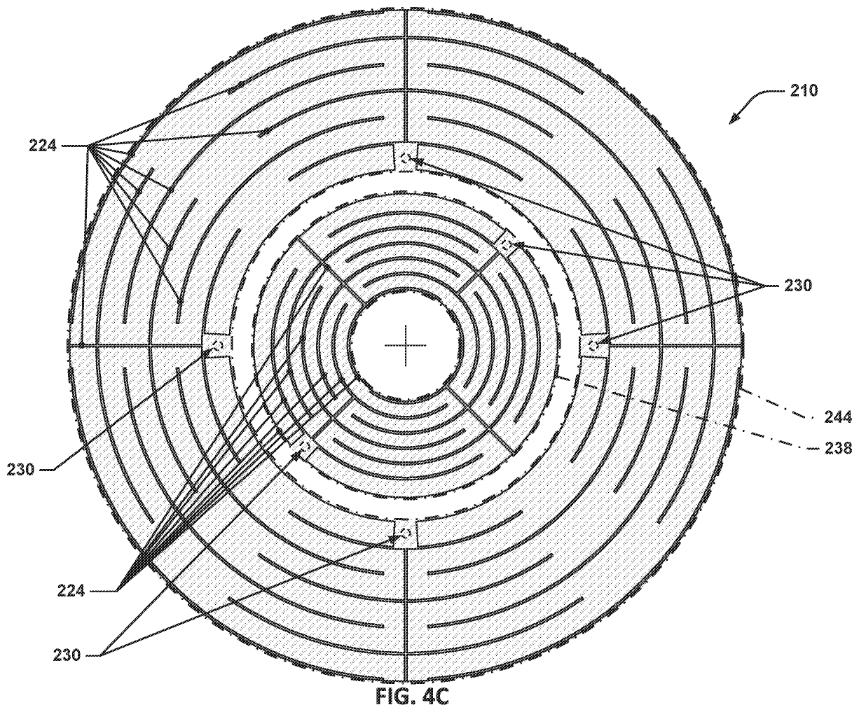

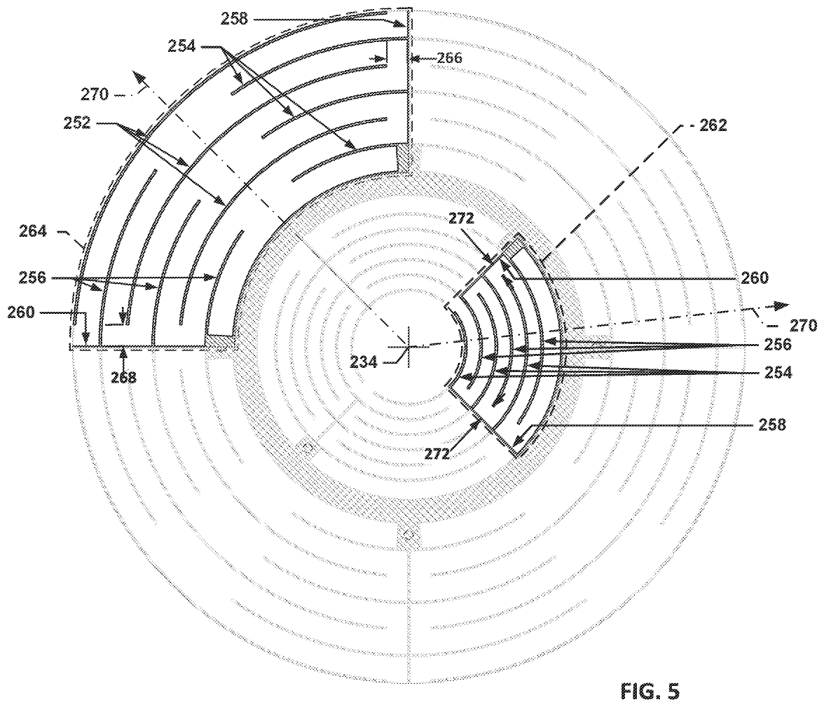

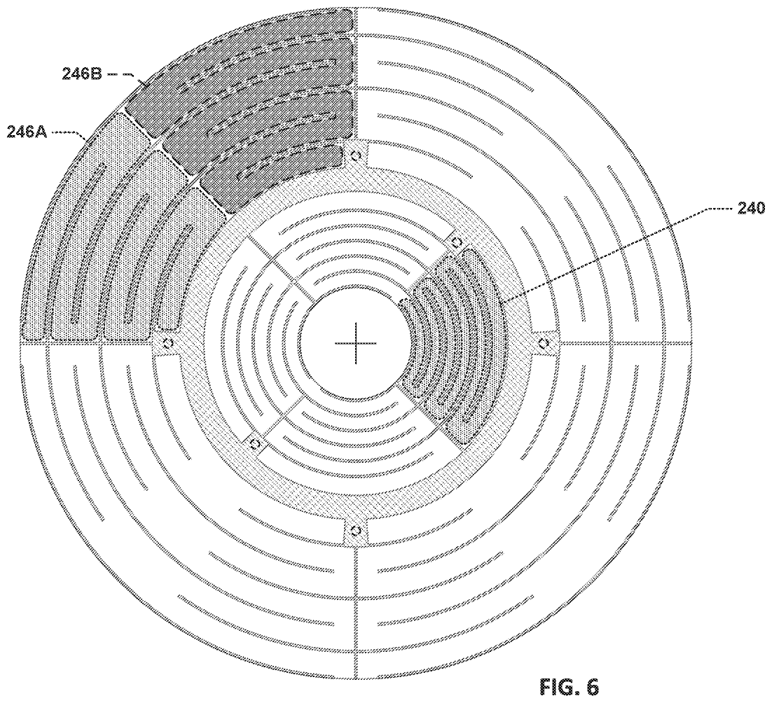

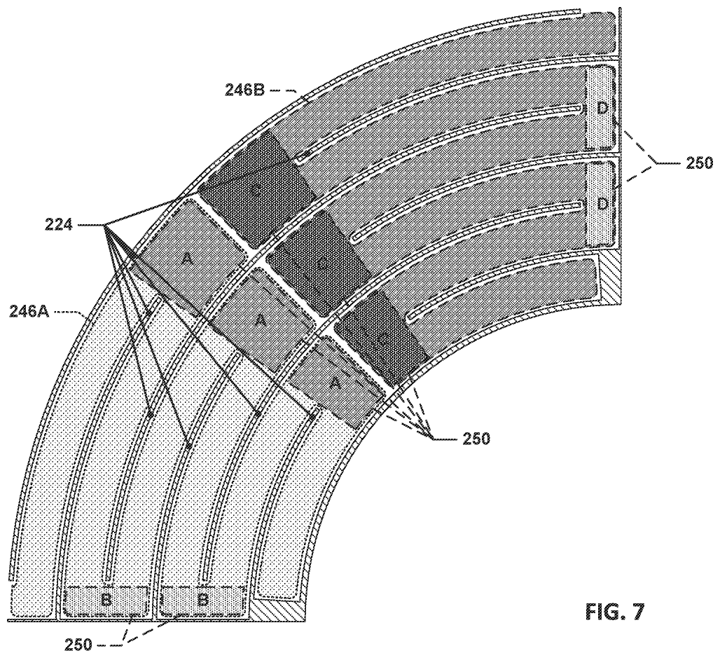

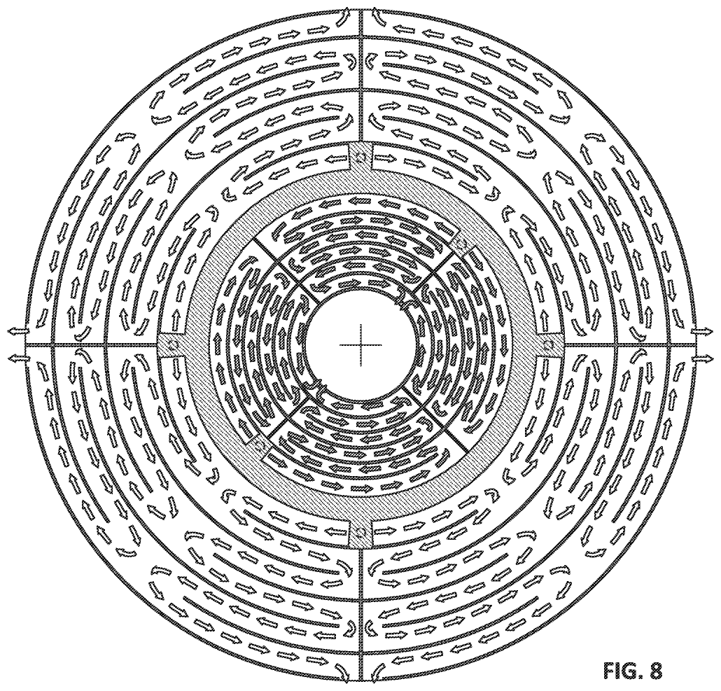

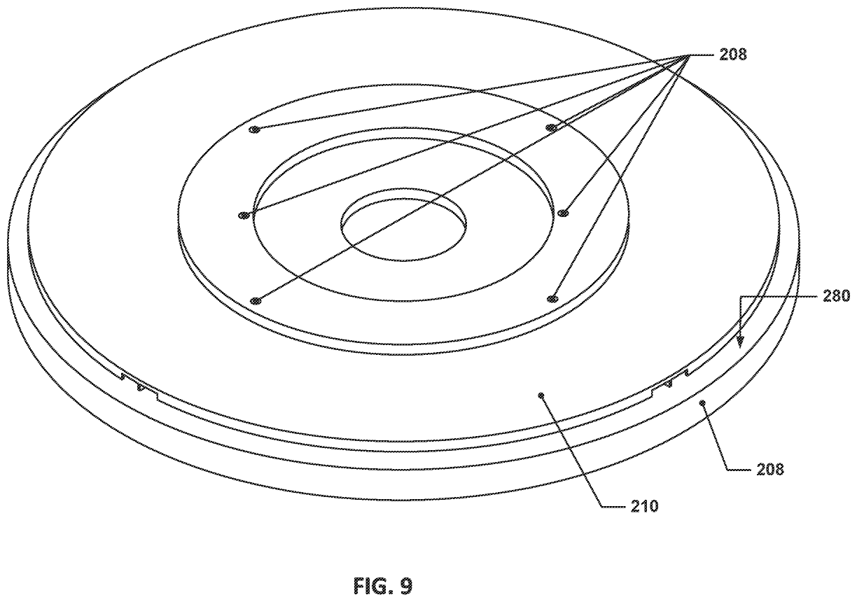

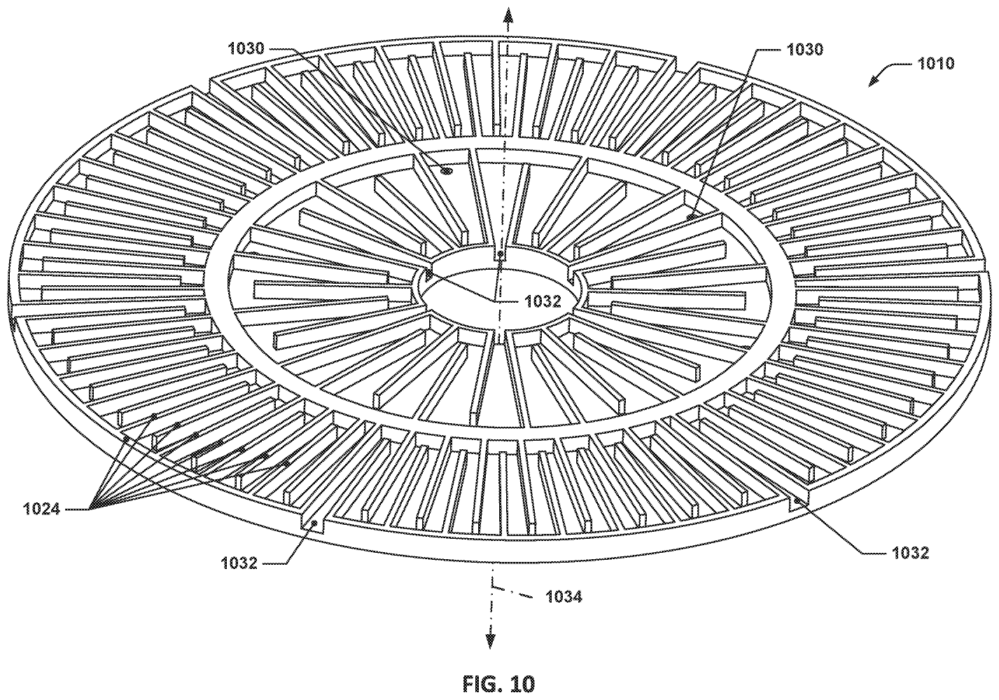

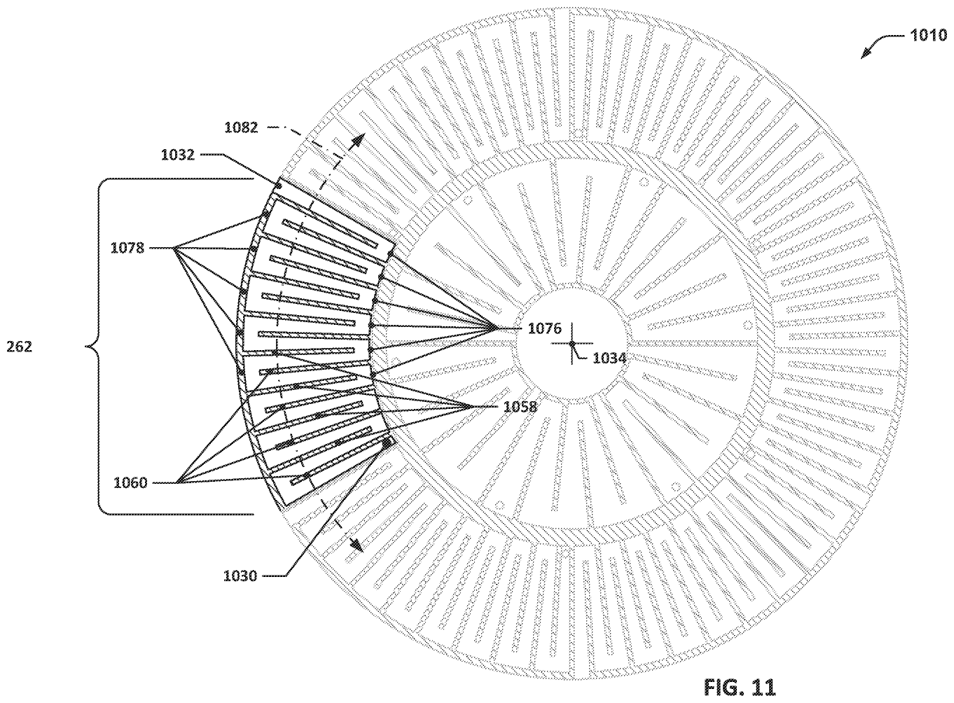

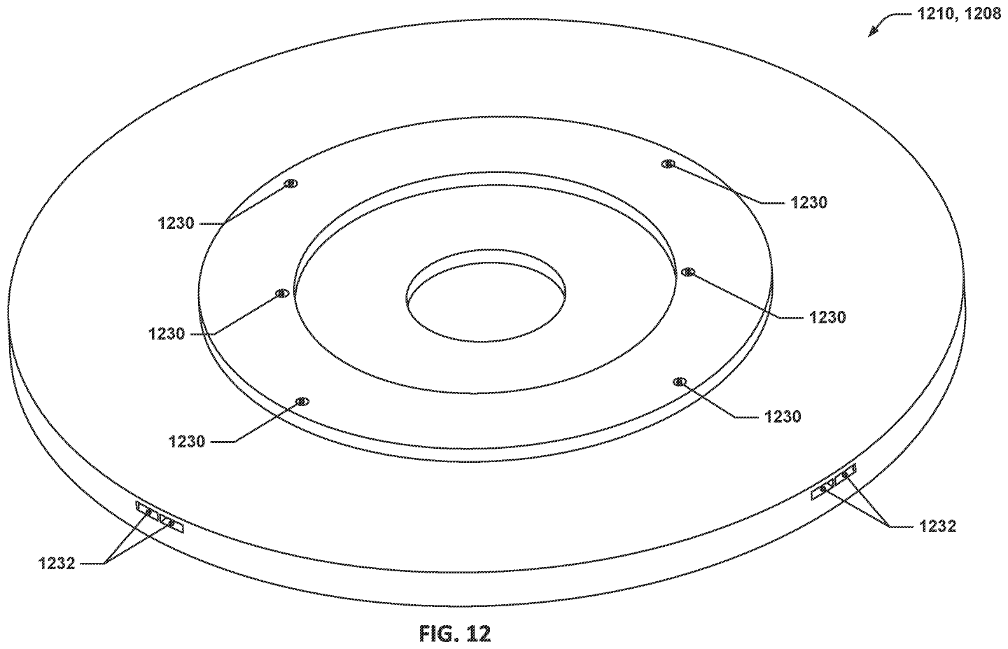

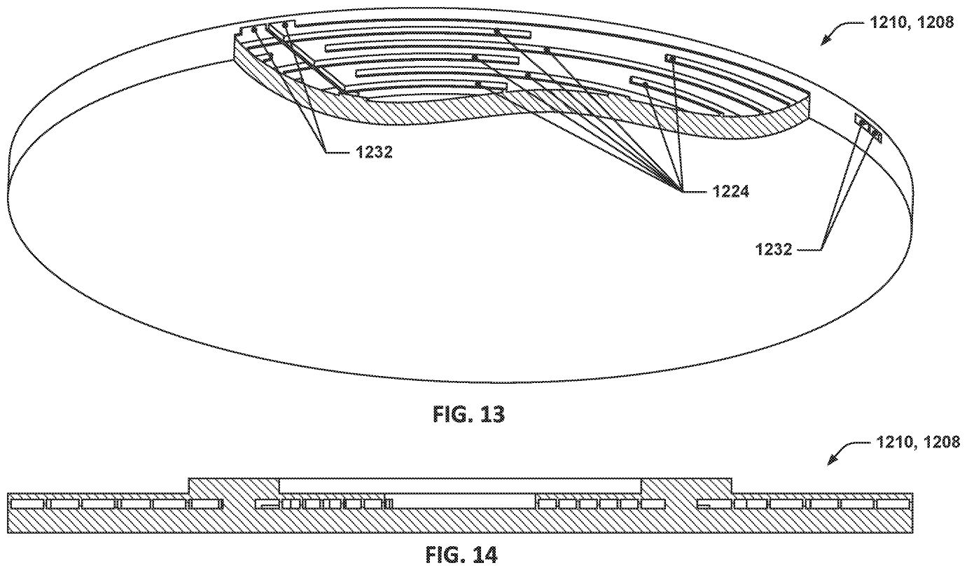

FIG. 4C depicts the plan view of FIGS. 4A and 4B, but showing annular areas associated with each set of walls.

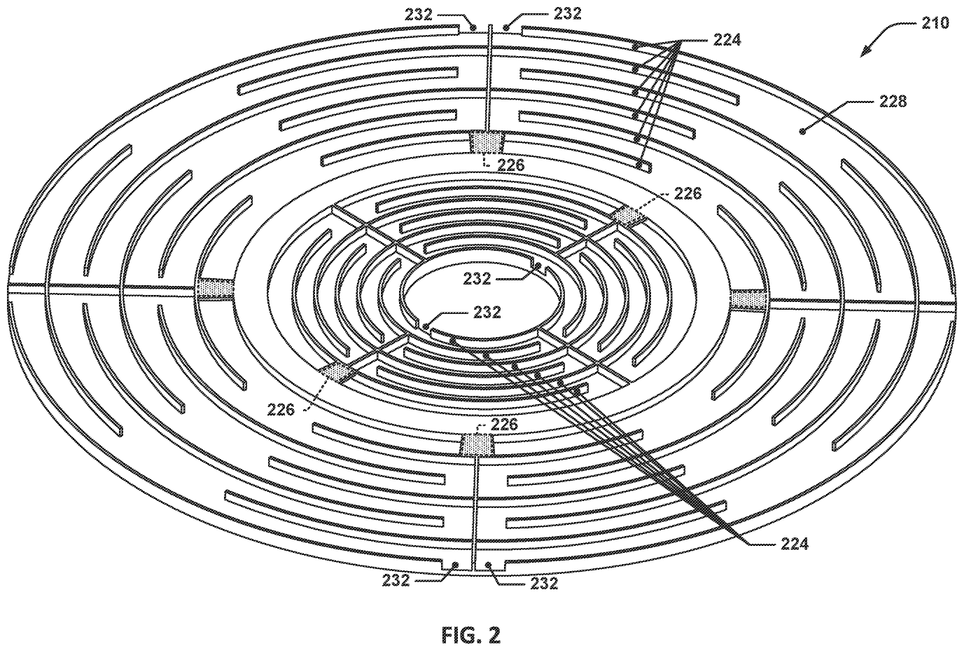

FIG. 5 depicts a plan view of the example cooling plate of FIG. 2 emphasizing a subset of walls of a first set of walls and a subset of walls of a second set of walls.

FIG. 6 depicts a plan view of the example cooling plate of FIG. 2 showing various serpentine channels.

FIG. 7 depicts a detail view of two of the serpentine channels of FIG. 6.

FIG. 8 depicts a plan view of the example cooling plate of FIG. 2 showing air fluid paths within the serpentine channels.

FIG. 9 depicts the example cooling plate of FIG. 2 placed above a window, as it may be when assembled into a semiconductor processing tool.

FIG. 10 depicts a perspective view of the underside of another example cooling plate.

FIG. 11 depicts a plan view of the cooling plate of FIG. 10 emphasizing a subset of walls of a set of walls.

FIG. 12 depicts a perspective view of an example cooling plate that is combined with the window into one, integrated structure.

FIG. 13 depicts a perspective partial cutaway view of the underside of the example cooling plate of FIG. 12.

FIG. 14 depicts a side section view of the example cooling plate of FIG. 12.

### DETAILED DESCRIPTION

As noted earlier, the cooling systems discussed herein may include a cooling plate with a ceiling portion and a plurality of walls extending from the ceiling portion. The walls may extend from the ceiling portion in a direction generally perpendicular to the ceiling portion; when the cooling plate is in an in-use configuration, e.g., placed on top of a window of a semiconductor processing chamber, the walls may extend downwards from the ceiling portion and towards the window. As also noted earlier, such a cooling plate may have one or more sets of walls, with each set of walls defining a plurality of serpentine channels that are distributed in a circular array within a corresponding annular region. Further details and features of such cooling systems are discussed below with respect to the Figures.

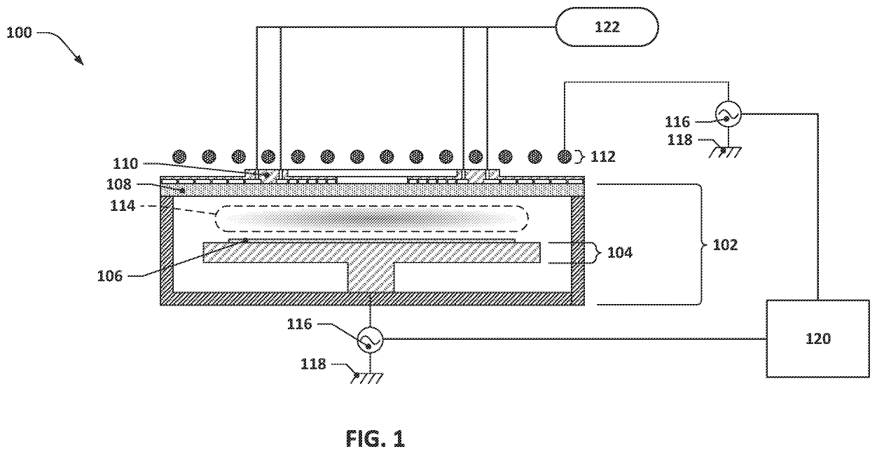

As noted above, the cooling plates discussed herein may be used in semiconductor processing chambers or tools that feature an RF-transmissive window that forms part of the chamber, e.g., the ceiling portion; an example of such a piece of equipment is a TCP reactor; FIG. 1 depicts an example of such a TCP reactor.

In FIG. 1, a semiconductor processing tool 100 is depicted. The semiconductor processing tool 100 may include a chamber 102 that includes a window 108 and a pedestal or wafer support 104 that supports a wafer 106 within the chamber 102. The window 108 may be made from an RF-transmissive material, such as quartz, and may act to allow pressure conditions within the chamber 102 to be maintained, contain processing gases within the chamber 102, and permit RF energy to be transmitted from an external RF generator, such as one of the RF generators 116 connected with grounds 118, via a coil 112 to the interior of the chamber 102, where the RF energy may energize a plasma 114 that may be used, for example, to etch the wafer 106. The RF generators 116 may, for example, be controlled by a controller 120, which may also control other equipment, e.g. valves, mass flow controllers, heaters, etc., that may be used to provide functionality in the semiconductor processing tool 100.

Also visible in FIG. 1 is a cooling plate 110, which may be a cooling plate as discussed in more detail below. The cooling plate 110 may be connected with one or more fluid sources 122, e.g., a CDA source (or, if liquid heat exchange fluid is being used, a liquid source), that may provide fluid at a positive gauge pressure to the cooling plate 110 via one or more tubes, hoses, or pipes; in some implementations, the tubes, hoses, or pipes that supply fluid to the serpentine channels defined by one or more different sets of walls in the cooling plate 110 may be controlled by one or more valves that are configured to allow for the amount of fluid flow to the serpentine channels of each set of walls to be individually adjusted.

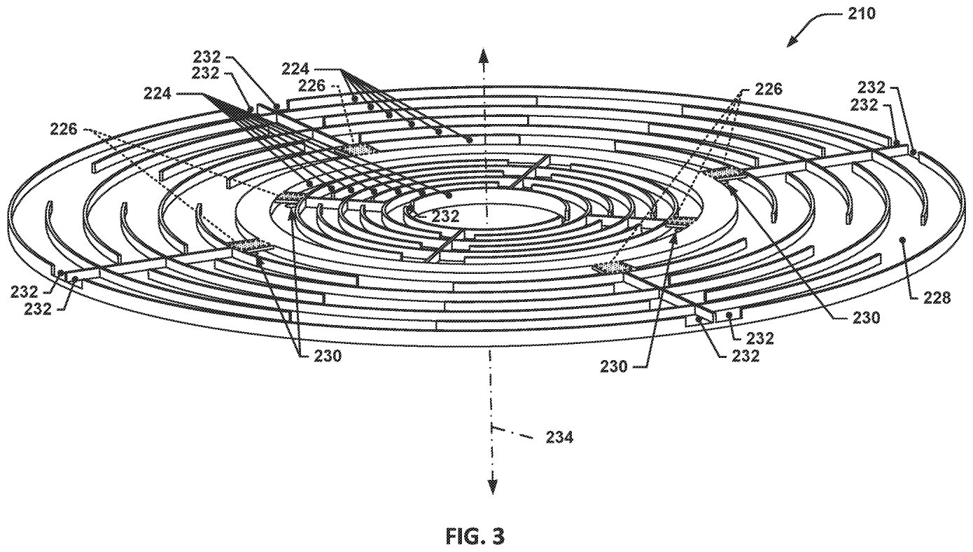

FIG. 2 depicts an isometric view of the underside of an example cooling plate. The example cooling plate 210 may include a ceiling portion 228, which, in this case, is generally provided by an annular or washer-shaped surface of the cooling plate, with a plurality of walls 224 extending therefrom. The walls 224 may define a plurality of serpentine channels, as will be discussed in more detail with reference to later Figures. The cooling plate 210 may also include one or more fluidic inlets (not shown, but see later Figures) and a plurality of fluidic outlets 232; each fluidic outlet 232 may, in many cases, generally be located at an opposite end of one of the serpentine channels from a fluidic inlet. In the depicted example, the fluidic outlets 232 are all located on outward- or inward-facing exterior surfaces of the cooling plate 210 so that fluid flowing out of the fluidic outlets 232 would generally flow in a direction perpendicular to a first axis 234 (as shown in FIG. 3), which is an axis that is generally perpendicular to the window and/or wafer and may be nominally centered on the wafer center (when the wafer is present and the cooling plate is in use). In other implementations, some or all of the fluidic outlets may be positioned in other locations (not shown), e.g., in the ceiling portion 228, such that the fluid exiting those fluidic outlets flows in an upward direction, e.g., away from the window; such alternate locations of the fluidic outlets (not shown) may be particularly useful in implementations in which there may be more than two sets of walls, each set of walls defining serpentine channels for a different annular area—the outermost and innermost sets of walls may have fluidic outlets 232 as shown, but the other sets of walls, e.g., those defining serpentine channels that are located in annular regions between the annular regions for the innermost and outermost sets of walls, may have fluidic outlets that are located, for example, in the ceiling portion 228.

As can also be seen in FIG. 2, the cooling plate 210 may also include, in some implementations, floor portions 226; the floor portions 226, in this case, are small, thin “bridges” of material that span between various adjacent walls 224. The depicted floor portions 226 are, in this example, each located so as to overlap a corresponding fluidic inlet when viewed along the first axis 234. Thus, fluid that is flowed into the fluidic inlets would first strike the floor portions 226 that are beneath those respective fluidic inlets before reaching the window that may lie beneath the floor portions 226 when the cooling plate 110 is in an in-use configuration. This may, for example, provide protection against or mitigate the formation of localized cold spots in the window beneath those fluidic inlets; such cold spots may, depending on the severity and other factors, adversely impact the performance of the window and may lead to an increased chance of window failure, e.g., due to thermal shock. The floor portions 226 may, in such cases, lessen such effects.

FIG. 3 depicts a perspective view of the underside of the example cooling plate of FIG. 2 showing further details thereof. Many of the features discussed above with respect to FIG. 2 are also visible in FIG. 3, although due to the shallower viewing angle used, fluidic inlets 230 beneath each floor portion 226 are also visible. It will be noted that each floor portion 226 may also act as a form of flow divider, as the fluid that is flowed through the corresponding fluidic inlet 230 may generally be caused by the floor portion 226 (or the window, if the floor portions 226 are not used and the cooling plate 210 is in an in-use configuration) to split into two distinct streams of fluid, each flowing down a different serpentine channel. In other implementations, however, two fluidic inlets 230 may be provided in a side-by-side configuration where there is an additional wall 224 between the two fluidic inlets 230 such that each fluidic inlet 230 supplies fluid to only a single serpentine channel.

As discussed, a cooling plate according to the present disclosure may have one or more sets of walls. FIG. 4A depicts a plan view of the underside of the example cooling plate of FIG. 2 emphasizing a first set of walls, FIG. 4B depicts the plan view of FIG. 4A but emphasizing a second set of walls, and FIG. 4C depicts the plan view of FIGS. 4A and 4B, but showing annular areas associated with each set of walls.

As can be seen in FIG. 4A, the cooling plate 210 has a first set 236 of walls 224 (shown in black, along with the floor portions 226 thereof; the remainder of the cooling plate 210 is shown in grey). As further shown in black in FIG. 4B, the cooling plate 210 also has a second set 242 of walls 224 (also shown in black, similar to how the first set 236 of walls 224 was shown in FIG. 4A). As will be noted with respect to FIG. 4C, the walls 224 of the first set 236 are all located within a first annular region 238, which is the smallest annular region that includes the entire first set 236 of walls 224. In this example, the first annular region 238 is smaller than, and fluidically separate from, the second annular region 244 although in some implementations, such annular regions may be fluidically connected, e.g., served by the same fluidic inlets 230. Similarly, the walls 224 of the second set 242 are all located within a second annular region 244. The fluidic inlets 230 which are shown are indicated in broken lines to indicate that they would actually, in this particular example, be obscured from view in this view by the floor portions 226 (not indicated, but see earlier Figures). Generally speaking, each set of walls 224 for a given cooling plate 210 may have a corresponding annular region that is the smallest annular region in which all of the walls 224 of that set of walls 224 are located. In some implementations, there may be only one annular region and one set of walls 224. In yet other implementations, there may be more than two annular regions and two sets of walls 224.

Each set of walls may have within it a plurality of subsets of walls; one or more of the subsets of walls for a given set of walls may be replicated in a circular pattern centered on the first axis 234. FIG. 5 depicts a plan view of the example cooling plate of FIG. 2 emphasizing a subset of walls of a first set of walls and a subset of walls of a second set of walls. As can be seen, the first set 236 of walls 224 of the cooling plate 210 includes a first subset 262 of walls 224, and the second set 242 of walls 224 of the cooling plate 210 includes a second subset 264 of walls 224. As will be evident, three additional instances of the second subset 264 of walls 224 are replicated in a circular array about the first axis 234, with each second subset 264 of walls 224 occupying a quadrant of the second annular region 244. The first subset 262 of walls 224 is replicated once in a two-instance circular pattern about the first axis 234. It will be noted that the first set 236 of walls 224 further includes two instances of another subset of walk 224, each of which occupies another quadrant of the first annular region 238 that is different from the quadrants occupied by the two first subsets 262 discussed earlier; these further two instances of the other subsets of walls 224, in this example are mirror images of the first subset 262 of walls 224. Thus, the first set 236 of walls 224 includes two different subsets of walls 224 that are arranged in two corresponding two-instance circular patterns about the first axis 234 and 90° out of phase with each other.

It will be understood that different cooling plates 210 may feature different numbers of subsets of walls 224; in the depicted example, each set of walls 224 includes four subsets of walls 224, but other implementations may include a set or sets of walls that feature more or fewer numbers of subsets, e.g., two subsets, three subsets, five subsets, six subsets, seven subsets, eight subsets, etc. Different sets of walls 224 for the same cooling plate 210 may also, in some implementation, have multiple sets of walls 224, two or more of which may have different numbers of subsets of walls.

The walls 224 of each subset may, depending on the particular implementation, include various specific types of walls. For example, the first subset 262 of walls 224 includes a first radial wall 258, a second radial wall 260, a plurality of first peninsular walls 254, and a plurality of second peninsular walls 256. For clarity, “radial walls,” as the term is used herein, are walls 224 that extend in a generally radial direction with respect to the first axis 234, although such walls do not necessarily have to be parallel to an axis that radiates outward from the first axis 234. Radial walls, as the phrase is used herein, may generally be characterized as being walls that extend from a point along or near the interior of the annular region within which they are located to a point along or near the exterior of the annular region within which they are located; such radial walls may be straight (as in the pictured example), slanted (i.e., at an oblique angle to a radius radiating outward from the first axis 234) or non-linear (for example, alternating short, straight segments in a zig-zag pattern or having a curved profile). Peninsular walls, as the phrase is used herein, may be generally characterized as being walls that have one end that is directly adjacent to or touching another wall while the other end thereof does not touch another wall and is spaced apart therefrom by some distance, thereby giving the appearance of a peninsula.

As can be seen in FIG. 5, the first peninsular walls 254 extend outward, e.g., in a generally circumferential direction, from the first radial wall 258 towards the second radial wall 260. Conversely, the second peninsular walls 256 extend outward, e.g., in a generally circumferential direction, from the second radial wall 260 towards the first radial wall 258. The ends of the first peninsular walls 254 and the second peninsular walls 256 that are closest to the second radial wall 260 and the first radial wall 258, respectively, are separated therefrom by a corresponding gap 272. It will be observed that the first peninsular walls 254 and the second peninsular walls 256 are arranged in an alternating manner along a second axis 270 that radiates outward from, and is perpendicular to, the first axis 234. This causes the first peninsular walls 256 and the second peninsular walls 258 to be interleaved with one another, e.g., each pair of adjacent first peninsular walls 256 has a second peninsular wall 258 interposed therebetween, and each pair of adjacent second peninsular walls 258 has a first peninsular wall 256 interposed therebetween.

It will be appreciated that more or fewer peninsular walls may be used, as desired, depending on packaging constraints and desired cooling efficacy. Furthermore, it will be appreciated that an odd number of peninsular walls may be used as well, if desired. The size of the corresponding gaps 272 may be set to any of a variety of values that do not adversely affect fluid flow through the serpentine channel(s) defined by the walls 224 of the first subset 262. For example, the corresponding gaps 272, in this example, vary somewhat from peninsular wall to peninsular wall, but are generally of a similar size as the radial gap that separates each peninsular wall from its neighboring peninsular wall (or walls).

As with the first subset 262 the second subset 264 of walls 224 also features a first radial wall 258, a second radial wall 260, first peninsular walls 254, and second peninsular walls 256, but the second subset 264 has a slightly different configuration of the peninsular walls and also features island walls 252. Island walls, as the phrase is used herein, refer to walls 224 that are separated from any nearby walls 224 by a gap (at both ends and along both sides). In the second subset 264, the first peninsular walls 254 and the second peninsular walls 256, as with the analogous walls 224 in the first subset 262, extend outward, towards each other, from the first radial wall 258 and the second radial wall 260, respectively, but, unlike the analogous walls 224 in the first subset 262, the first peninsular walls 254 and the second peninsular walls 256 of the second subset 264 are arranged as opposing pairs of walls. Each opposing pair of peninsular walls 254 and 256 are generally symmetric about a radial axis that extends outward from the first axis 234 (similar to the second axis 270 shown passing through the second subset 264). The first peninsular walls 254 and the second peninsular walls 256 of the second subset 264 thus do not overlap one another when viewed along a radial axis radiating out from the first axis 234, thereby causing a gap to exist between the ends of the first peninsular walls 254 and the second peninsular walls 256 of each pair of peninsular walls in the second subset 264.

The island walls 252 may be arranged to be positioned generally midway between the first radial wall 258 and the second radial wall 260, e.g., separated from the first radial wall 258 by a first gap 266 and from the second radial wall 260 by a second gap 268, with the island walls 252 and the pairs of first peninsular walls 254 and second peninsular walls 256 arranged in an alternating fashion along the second axis 270 that passes through the second subset 264.

As likely already apparent, the walls 224 of the cooling plate 210 discussed above may form a plurality of serpentine channels. In the interest of clarity, FIG. 6 depicts a plan view of the example cooling plate of FIG. 2 showing the serpentine channels for the first subset 262 and the second subset 264 shown in FIG. 5. As can be seen, the first subset 262 of walls 224 forms a first serpentine channel 240, and the second subset 264 of walls 224 forms two second serpentine channels 246A and 246B; these serpentine channels (or mirror images thereof) are replicated in circular arrays about the first axis 234, although these additional serpentine channels are not explicitly indicated in FIG. 6.

FIG. 7 depicts a detail view of two of the serpentine channels of FIG. 6. In FIG. 7, the second subset 264 of walls 224 is shown in isolation, with the two second serpentine channels 246A and 246B indicated. Serpentine channels, as the phrase is used herein, refer to channels that follow a generally serpentine path, e.g., a path that follows a winding or meandering course, such as, for example, a path that includes a plurality of parallel/straight or concentric/curved longer segments extending between two regions, with the end of each such longer segment generally connected, by a shorter segment, with the closest end or one of the two closest ends of another such longer segment (except for the start and end of such a path, which may not feature such shorter segments).

As can be seen in FIG. 7, each second serpentine channel 246A/B features a plurality of flow reversal sections 250; each flow reversal section 250 represents a region of one of the second serpentine channels 246A/B in which flow from the portion of that second serpentine channel 246A or 246B immediately upstream of that flow reversal section 250 generally reverses direction before flowing down the portion of that second serpentine channel 246A or 246B immediately downstream of that flow reversal section 250. In FIG. 7, the second serpentine channel 246A includes flow reversal sections 250 marked as “A” (which may be referred to herein as “first flow-reversal sections”) and “B” (which may be referred to herein as “second flow-reversal sections”); similarly, the second serpentine channel 246B includes flow reversal sections 250 marked as “C” (which may also be referred to herein as “first flow-reversal sections”) and “D” (which may also may be referred to herein as “second flow-reversal sections”). It will be generally observed that fluid flowing from the fluidic inlets 230 (not shown) to the fluidic outlets 232 (not indicated, but located at the upper right corner and lower left corner of the Figure) will pass through alternating first flow-reversal sections (A or C) and second flow reversal sections (B or D) as it travels along the second serpentine channel 246A or 246B.

It will be noted that the second serpentine channels 246A and 246B are not actually separated entirely from one another by walls 224—they are, in fact, fluidically adjacent. Fluidically adjacent, as the phrase is used herein, refers to two volumes that are directly adjacent to one another such that they would generally be considered to be sub-volumes of the same fluidic volume. For example, two discrete fluid channels that may each be considered to have their own fluidic volumes might share a common wall for some distance; if a portion of that wall were to be removed, allowing the fluids in each channel to come into contact, the fluidic volumes of each of the channels in that region where the portion of the wall was removed would be considered to be “fluidically adjacent” in the context of this disclosure. Fluids from volumes that are fluidically adjacent may very well cross from one volume to the other, or vice versa. In the case of the second serpentine channels 246A and 246B, the first flow-reversal sections 250 (A and C) are fluidically adjacent, which may allow fluid from the serpentine channel 246A to cross over into the serpentine channel 246B (or vice versa). For the purposes of this disclosure, however, such fluidically adjacent serpentine channels are still considered to be serpentine channels despite the first flow-reversal portions 250 (A and C) being fluidically adjacent. Generally speaking, if the flow rates in each serpentine channel are the same, the fluid that flows through such arrangements of serpentine channels may generally reverse direction in the flow reversal sections, even if there is no wall separating the flow reversal section from an adjacent flow reversal section of another serpentine channel. For example, if two fluid streams are directed towards each other, each fluid stream will push back against the other fluid stream, generally causing the other fluid stream to change direction, e.g., to make a sharp turn away from the path that the fluid stream had been following. In this case, the fluid streams would generally change direction to both flow radially outward until they struck the island wall 252 that defines part of the flow-reversal sections 250, at which point the fluid streams would again generally split apart and travel in opposing directions. As noted above, some fluid from one second serpentine channel 246A or 246B may cross over into the other second serpentine channel 246A or 246B; this is to be expected and should not be viewed as affecting the interpretation

FIG. 8 depicts a plan view of the example cooling plate of FIG. 2 showing air fluid paths within the serpentine channels. As can be seen, the fluid that is flowed into the cooling plate 210 through the fluidic inlets 230 for the first set 236 of walls 224 flows through the plurality of first serpentine channels 240 in a meandering, radially inward direction, and the fluid that is flowed into the cooling plate 210 through the fluidic inlets 230 for the second set 242 of walls 224 flows through the plurality of second serpentine channels 246 in a meandering, radially outward direction. This provides distributed cooling across the window that the cooling plate 210 may be mounted adjacent to.

FIG. 9 depicts the example cooling plate of FIG. 2 placed above a window, as it may be when assembled into a semiconductor processing tool. The walls 224 of the cooling plate 224 may, as shown, be pressed into contact with a top surface 280 of a window 208, effectively turning the “open” serpentine channels of the cooling plate 210 into “enclosed” channels. In some implementations, the walls 224 may be adhered to, or otherwise interfaced with, the top surface of a window, e.g., using a double-sided pressure-sensitive adhesive, thermal interface material, and/or gasket, to reduce the amount of fluid that may leak from one portion of a channel to another between any small gaps that may exist between the walls 224 and the top surface 280 of the window 208. For clarity, the term “open” channel or the like is used herein to refer to a channel structure in which the channel structure is open along at least one side along its length, e.g., it has a floor and opposing side walk, but no ceiling, or vice-versa. Put another way, an open channel has an open cross-section taken in a plane that is perpendicular to the path followed by the channel. Thus, fluid that flows through an open channel would be able to leave the open channel at any point along its length if subjected to a suitable urging force. In contrast, an enclosed channel, as the term is used herein, refers to a channel where the channel is enclosed on all sides between the inlet(s) and outlet(s) for the channel, e.g., the channel is like a tunnel. Put another way, an enclosed channel has a closed cross-section taken in a plane that is perpendicular to the path followed by the channel. Fluid that flows through an enclosed channel can only leave the enclosed channel via an outlet and only enter the enclosed channel via an inlet. It will be understood that an enclosed channel may transition to an open channel, and vice versa, in which case the inlet and outlet of each may be deemed to exist at the transition point for each channel. In cooling plate implementations which feature open channels, the cooling plate may be placed adjacent to the window such that the window further defines the serpentine channels that are defined, in part, by the walls and ceiling portion of the cooling plate. The window may, in such implementations, may turn the open channels of the cooling plate into, in effect, enclosed channels when the cooling plate is placed against the window.

As is evident from the previous example, a cooling plate according to the present disclosure may have walls 224 that are a mixture of arcuate and straight walls that may be arranged to produce serpentine channels that follow predominantly arcuate paths. Other implementations, however, may be configured to generate serpentine channels that predominantly follow other paths, e.g., linear paths. An example of such an alternate cooling plate follows.

FIG. 10 depicts a perspective view of the underside of another example cooling plate. In FIG. 10, a cooling plate 1010 is shown; as will be evident, the cooling plate 1010 is similar in overall size and form factor to the cooling plate 210 discussed earlier; due to this similarity and out of a desire to reduce visual clutter, features that are similar in both cooling plates 210 and 1010 may not be separately called out in FIG. 10 but should still be understood to be present, e.g., the ceiling portion of the cooling plate 1010 is not separately called out but is present nonetheless.

The cooling plate 1010, it will be noted, has, as with the cooling plate 210, two sets of walls 1024, although additional sets of walls (or fewer) may be used instead. Unlike the cooling plate 210, in which there were four subsets of walk 224 in each of the two sets of walk 224, each set of walls 1024 in the cooling plate 1010 has six subsets of walls, each of which defines a separate serpentine channel. Additionally, the cooling plate 1010 also features a single fluidic inlet 1030 and a single fluidic outlet 1032 for each subset and each serpentine channel, although other implementations may see fluidic inlets 1030 and/or fluidic outlets 1032 be shared between two subsets or serpentine channels, or may see multiple fluidic inlets 1030 and/or fluidic outlets 1032 provided for a single subset and/or serpentine channel.

As noted above, the cooling plate 1010 exhibits a different arrangement of walls 1024 compared to the cooling plate 210. Such an arrangement is discussed below with respect to FIG. 11, which depicts a plan view of the cooling plate of FIG. 10 emphasizing a subset of walls of a set of walls. In FIG. 11, a first subset 1062 of walls 1024 of a first set of walls (not indicated, but the walls 1024 in the outer annular area of the cooling plate 1010) is shown in black, with the remainder of the structure of the cooling plate 1010 shown in grey. The depicted first subset 1062 of walls 1024 may include, for example, an outer wall 1078, an inner wall 1076, a plurality of first radial walls 1058, and a plurality of second radial walls 1060. Each first radial wall 1058 extends from the outer wall 1078 radially inwards, while each second radial wall 1060 extends from the inner wall 1076 radially outward. The ends of the first radial walls 1058 and the second radial walls 1060 may, as shown in FIG. 11, be separated from the inner wall 1076 and the outer wall 1078, respectively, by gaps, thereby creating a serpentine channel by virtue of the alternating placement of the first radial walls 1058 and the second radial walls 1060 along an arcuate path 1082 that is centered on a first axis 1034 such that each pair of adjacent first radial walls 1058 has a second radial wall 1060 interposed therebetween and each pair of adjacent second radial walls 1060 has a first radial wall 1058 interposed therebetween.

The cooling plates discussed above with respect to the Figures are both designed to be separate components from the windows that each is configured to cool. However, as discussed earlier, other cooling plate designs may be integrated into the window itself. FIG. 12 depicts a perspective view of an example cooling plate that is combined with the window into one, integrated structure. In such implementations, the cooling plate may be considered to have a floor portion that extends from the innermost subset of walls, i.e., the walls that are closest to the first axis, to the outermost subset of walls, i.e., the walls that are furthest from the first axis. Thus the floor portion may at least extend over an annular or circular area, and the walls of each set of walls may span between the ceiling portion and the floor portion.

As can be seen in FIG. 12, a cooling plate 1210 is provided that also serves as a window 1208. The cooling plate 1210/window 1208 (which may be referred to below in either sense with the understanding that a reference to the cooling plate 1210 is also a reference to the window 1208, and vice-versa) features fluidic inlets 1230 that are each fluidically connected with one or more of fluidic outlets 1232 by serpentine channels within the cooling plate 1210.

FIG. 13 depicts a perspective partial cutaway view of the underside of the example cooling plate of FIG. 12; FIG. 14 depicts a side section view of the example cooling plate of FIG. 12. As can be seen in FIG. 13, part of the window 1208 has been cut away, showing the walls 1224 that are housed within the cooling plate 1210. Such a combined cooling plate 1210 and window 1208 may, as noted earlier, provide for a more integrated cooling system approach that may result in more effective cooling performance.

The cooling plates discussed herein may be made of a variety of RF-transmissive materials so as to avoid or reduce interference with the transmission of RF energy through the windows with which they are used. Such materials may include, for example, ceramics, such as aluminum oxide or aluminum nitride, quartz, or other material having a similar level of RF transmissivity. It will be recognized that the cooling plates discussed herein may be manufactured using any of a number of manufacturing techniques, including, but not limited to, machining, casting, molding, additive manufacturing (3D printing), and so forth.

As noted earlier, the cooling plates discussed herein may be connected with one or more air sources, e.g. a CDA source, via one or more fluid conduits, e.g., tubes hoses, etc. The flow of cooling fluid, e.g., CDA, to each fluidic inlet of the cooling plate may, in some instances, be regulated by a restrictor plate, valve, or other fluid flow control device or structure. In some instances, a controller may control the flow of fluid to the cooling plate, e.g., by controlling one or more valves.

The controllers discussed above may be part of a system that may include the above-described examples, and may be operatively connected with various valves, mass flow controllers, pumps, etc. so as to be able to receive information from and/or control such equipment. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of various gases, temperature settings (e.g., heating and/or cooling), pressure settings, vacuum settings, power settings, flow rate settings, fluid delivery settings, and positional and operation settings.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some implementations, be part of a recipe defined by process engineers to accomplish one or more processing steps during the fabrication of one or more layers, materials, metals, oxides, silicon, silicon dioxide surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module a metal plating chamber or module, a dean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, duster took, other tool interfaces, adjacent took, neighboring took, took located throughout a factory, a main computer, another controller, or took used in material transport that bring containers of wafers to and from tool locations and/or load ports in a semiconductor manufacturing factory.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood.

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
a cooling plate having:
a ceiling portion;
one or more sets of walls; and
a plurality of fluidic inlets, wherein:
the walls in each set of walls define, at least in part, a plurality of serpentine channels,
each serpentine channel has a first end and a second end,
the serpentine channels defined by each set of walls are arranged in one or more circular patterns centered on a first axis of the cooling plate,
the walls in each set of walls protrude from the ceiling portion in a direction having a major component parallel to the first axis,
each fluidic inlet is fluidically connected with the first end of at least one of the serpentine channels within the cooling plate, and
a semiconductor processing chamber having a radio-frequency transmissive window, wherein the cooling plate is positioned against the window such that the window further defines the serpentine channels.

2. (canceled)

3. The apparatus of claim 1, further comprising a pressurized air source, wherein the pressurized air source is fluidically connected with at least one of the one or more fluidic inlets.

4. The apparatus of claim 1, wherein:
the one or more sets of walls includes a first set of walls and a second set of walls, and
the first set of walls occupies a first annular region that has an outer diameter that is smaller than an inner diameter of a second annular region occupied by the second set of walls.

5. The apparatus of claim 1, wherein:
the serpentine channels defined by at least one set of walls of the one or more sets of walls are open channels.

6. The apparatus of claim 5, wherein the cooling plate further includes one or more floor portions, wherein each floor portion is:
positioned so as to overlap one of the fluidic inlets when viewed along the first axis, and
offset from the ceiling portion so as to form a gap between the ceiling portion and that floor portion.

7. The apparatus of claim 1, wherein the cooling plate further includes a floor portion, wherein:
the walls include a first subset of walls that are closest to the first axis and a second subset of walls that are furthest from the first axis,
the floor portion spans between the first subset of walls and the second subset of walls, and
the walls of each set of walls span between the ceiling portion and the floor portion.

8. The apparatus of claim 7, wherein the ceiling portion, the floor portion, and the walls of the one or more sets of walls are made of a material that is transmissive to radio frequency energy.

9. The apparatus of claim 1, wherein:
the one or more sets of walls includes a first set of walls,
the first set of walls defines multiple pairs of serpentine channels, with each pair of serpentine channels including a first serpentine channel and a second serpentine channel,
the first serpentine channel for each pair of serpentine channels includes a plurality of first and second flow-reversal sections such that fluid flowing from the first end to the second end of that first serpentine channel encounters the first and second flow-reversal sections thereof in an alternating fashion,
the second serpentine channel for each pair of serpentine channels includes a plurality of third and fourth flow-reversal sections such that fluid flowing from the first end to the second end of that second serpentine channel encounters the third and fourth flow-reversal sections thereof in an alternating fashion, and
the first flow-reversal sections of the first serpentine channel for each pair of serpentine channels and the third flow-reversal sections of the second serpentine channel for that pair of serpentine channels are fluidically adjacent.

10. The apparatus of claim 1, wherein:
the one or more sets of walls includes a first set of walls,
the first set of walls includes multiple subsets of walls, each subset of walls including a first radial wall, a second radial wall, one or more island walls, and one or more pairs of peninsular walls,
each first radial wall extends along a generally radial direction with respect to the first axis,
each second radial wall extends along a generally radial direction with respect to the first axis,
each pair of peninsular walls of each subset of walls includes a first peninsular wall that extends outward from the first radial wall of that subset of walls and a second peninsular wall that extends outward from the second radial wall of that subset of walls,
the first peninsular wall and the second peninsular wall of each pair of peninsular walls of each subset of walls extend outward and towards each other from the first radial wall of that subset of walls and the second radial wall of that subset of walls, respectively,
a gap exists between the first peninsular wall and the second peninsular wall of each pair of peninsular walls,
each island wall of each subset of walls is located between the first radial wall of that subset of walls and the second radial wall of that subset of walls,
a first gap exists between each island wall of each subset of walls and the first radial wall of that subset of walls,
a second gap exists between each island wall of each subset of walls and the second radial wall of that subset of walls, and
the one or more island walls of each subset of walls and one or more pairs of peninsular walls of that subset of walls are arranged in an alternating fashion along a corresponding second axis that intersects with, and is perpendicular to, the first axis such that one of the one or more island walls of that subset of walls is between every two adjacent pairs of peninsular walls of that subset of walls and one of the one or more pairs of peninsular walls of that subset of walls is between every two adjacent island walls of that subset of walls.

11. The apparatus of claim 10, wherein the radial walls and the peninsular walls of the first set of walls are all arcuate and concentric with one another.

12. The apparatus of claim 1, wherein the one or more sets of walls includes a first set of walls that includes multiple subsets of walls, each subset of walls including a first radial wall, a second radial wall, one or more first peninsular walls, and one or more second peninsular walls, and wherein, for each subset of walls:
each first radial wall extends along a generally radial direction with respect to the first axis,
each second radial wall extends along a generally radial direction with respect to the first axis,
each first peninsular wall for that subset of walls extends outward from the first radial wall for that subset of walls towards the second radial wall for that subset of walls,
each second peninsular wall for that subset of walls extends outward from the second radial wall of that subset of walls towards the first radial wall for that subset of walls,
each first peninsular wall for that subset of walls and each second peninsular wall for that subset of walls are separated from the second radial wall for that subset of walls and the first radial wall for that subset of walls, respectively, by a corresponding gap, and
the one or more first peninsular walls for that subset of walls and the one or more second peninsular walls for that subset of walls are arranged in an alternating fashion along a corresponding second axis that intersects with, and is perpendicular to, the first axis such that every two adjacent pairs of peninsular walls for that subset of walls has a portion of one of the one or more island walls for that subset of walls therebetween and every two adjacent island walls for that subset of walls has a portion of one of the one or more pairs of peninsular walls therebetween.

13. The apparatus of claim 1, wherein the one or more sets of walls includes a first set of walls that includes multiple subsets of walls, each subset of walls including an inner wall, an outer wall, one or more first radial walls, and one or more second radial walls and wherein, for each subset of walls:
each first radial wall for that subset of walls extends radially inward from the outer wall for that subset of walls and with respect to the first axis,
each second radial wall for that subset of walls extends radially outward from the inner wall for that subset of walls and with respect to the first axis,
the inner wall for that subset of walls is closer to the first axis than the outer wall for that subset of walls, and
the one or more first radial walls for that subset of walls and the one or more second radial walls for that subset of walls are arranged in an alternating fashion along an arcuate path centered on the first axis.

14. The apparatus of claim 1, wherein each set of walls is selected from the group consisting of (a) a first set of walls, (b) a second set of walls, and (c) a third set of walls, wherein:
each first set of walls of (a) includes multiple first subsets of walls, each first subset of walls including a first radial wall, a second radial wall, one or more island walls, and one or more pairs of peninsular walls, and wherein, for each first subset of walls:
each first radial wall extends along a generally radial direction with respect to the first axis,
each second radial wall extends along a generally radial direction with respect to the first axis,
each pair of peninsular walls for that first subset of walls includes a first peninsular wall that extends outward from the first radial wall of that first subset of walls and a second peninsular wall that extends outward from the second radial wall of that first subset of walls,
the first peninsular wall and the second peninsular wall of each pair of peninsular walls of that first subset of walls extend outward and towards each other from the first radial wall of that first subset of walls and the second radial wall of that first subset of walls, respectively,
a gap exists between the first peninsular wall and the second peninsular wall of each pair of peninsular walls for that first subset of walls,
each island wall of that first subset of walls is located between the first radial wall of that first subset of walls and the second radial wall of that first subset of walls,
a first gap exists between each island wall of that first subset of walls and the first radial wall of that first subset of walls,
a second gap exists between each island wall of that first subset of walls and the second radial wall of that first subset of walls, and
the one or more island walls of that first subset of walls and one or more pairs of peninsular walls of that first subset of walls are arranged in an alternating fashion along a corresponding second axis that intersects with, and is perpendicular to, the first axis such that one of the one or more island walls of that first subset of walls is between every two adjacent pairs of peninsular walls of that first subset of walls and one of the one or more pairs of peninsular walls of that first subset of walls is between every two adjacent island walls of that first subset of walls;
each second set of walls of (b) includes multiple second subsets of walls, each second subset of walls including a third radial wall, a fourth radial wall, one or more third peninsular walls, and one or more fourth peninsular walls, and wherein, for each second subset of walls:
each third radial wall extends along a generally radial direction with respect to the first axis,
each fourth radial wall extends along a generally radial direction with respect to the first axis,
each third peninsular wall for that second subset of walls extends outward from the third radial wall for that second subset of walls towards the fourth radial wall for that second subset of walls,
each fourth peninsular wall for that second subset of walls extends outward from the fourth radial wall of that second subset of walls towards the third radial wall for that second subset of walls,
each third peninsular wall for that second subset of walls and each fourth peninsular wall for that second subset of walls are separated from the fourth radial wall for that second subset of walls and the third radial wall for that second subset of walls, respectively, by a corresponding gap, and
the one or more third peninsular walls for that second subset of walls and the one or more fourth peninsular walls for that second subset of walls are arranged in an alternating fashion along a corresponding second axis that intersects with, and is perpendicular to, the first axis such that every two adjacent pairs of peninsular walls for that second subset of walls has a portion of one of the one or more island walls for that second subset of walls therebetween and every two adjacent island walls for that second subset of walls has a portion of one of the one or more pairs of peninsular walls therebetween; and
each third set of walls of (c) includes multiple third subsets of walls, each third subset of walls including an inner wall, an outer wall, one or more fifth radial walls, and one or more sixth radial walls and wherein, for each third subset of walls:
each fifth radial wall for that third subset of walls extends radially inward from the outer wall for that third subset of walls and with respect to the first axis,
each sixth radial wall for that third subset of walls extends radially outward from the inner wall for that third subset of walls and with respect to the first axis,
the inner wall for that third subset of walls is closer to the first axis than the outer wall for that third subset of walls, and
the one or more fifth radial walls for that third subset of walls and the one or more sixth radial walls for that third subset of walls are arranged in an alternating fashion along an arcuate path centered on the first axis.
